(19) United States
(12) Patent Application Publication
(10) Pub. No.: US 2016/0276267 A1
(43) Pub. Date: Sep. 22, 2016

(54) METHODS OF FORMING WIRING STRUCTURES IN A SEMICONDUCTOR DEVICE

(71) Applicants: Jong-Jin Lee, Seoul (KR); Rak-Hwan Kim, Suwon-si (KR); Byung-Hee Kim, Seoul (KR); Jin-Nam Kim, Anyang-si (KR); Tsukasa Matsuda, Seongnam-si (KR); Nae-In Lee, Seoul (KR); Jeong-Ok Cha, Seoul (KR); Jung-Ha Hwang, Gunpo-si (KR)

(72) Inventors: Jong-Jin Lee, Seoul (KR); Rak-Hwan Kim, Suwon-si (KR); Byung-Hee Kim, Seoul (KR); Jin-Nam Kim, Anyang-si (KR); Tsukasa Matsuda, Seongnam-si (KR); Nae-In Lee, Seoul (KR); Jeong-Ok Cha, Seoul (KR); Jung-Ha Hwang, Gunpo-si (KR)

(21) Appl. No.: 15/018,484

(22) Filed: Feb. 8, 2016

(30) Foreign Application Priority Data
Mar. 18, 2015 (KR) 10-2015-0037461

(51) Int. Cl. H01L 23/522; H01L 21/285; H01L 23/532; H01L 21/768

(52) U.S. Cl. CPC H01L 23/5226; H01L 21/76802; H01L 21/76843; H01L 21/76862; H01L 21/28556; H01L 21/28568; H01L 21/76873; H01L 21/76879; H01L 21/76864; H01L 23/53238

(57) ABSTRACT

Methods of forming wiring structures and methods of manufacturing semiconductor devices include forming a lower structure on a substrate, forming an interlayer insulating film including an opening on the lower structure, forming a liner film on an inner surface of the opening, treating a surface of the liner film by an ion bombardment, and forming a first conductive film on the liner film. The first conductive film is formed to be at least partially filled in the opening through a reflow process. Related wiring structures and semiconductor devices are also discussed.

### CLAIM OF PRIORITY

This application claims priority under 35 U.S.C. §119 to Korean Patent Application No. 10-2015-0037461 filed Mar. 18, 2015, in the Korean Intellectual Property Office, the disclosure of which is hereby incorporated by reference herein.

### BACKGROUND

Example embodiments of the inventive concepts relate to wiring structures, methods of forming wiring structures and methods of manufacturing semiconductor devices, and more particularly, to wiring structures including a plurality of conductive films, methods of forming the same, and methods of manufacturing semiconductor devices including the same.

Semiconductor devices may include wiring structures such as via structures and/or contacts for interconnecting signal lines that are respectively formed in different layers. For example, the wiring structure may be formed by forming an opening that exposes a lower conductive pattern and by filling a conductive film in the opening. As the integration degree of semiconductor devices becomes high, the width and spacing of the opening may be reduced. Accordingly, deposition characteristics of the conductive film in the opening may be degraded.

### SUMMARY

Example embodiments of the inventive concepts provide wiring structures having a fine size, methods of forming the same and methods of manufacturing semiconductor devices including the same.

According to some embodiments of the inventive concepts, in a method of forming a wiring structure in a semiconductor device, a conductive liner film is formed on an underlying conductive wiring layer that is exposed by an opening in an interlayer insulating layer, such that the conductive liner film extends on sidewalls of the opening. An ion bombardment is performed on a surface of the conductive liner film in the opening, such that the ion bombardment increases a wettability characteristic of the surface of the conductive liner film. A first conductive film is formed on the surface of the conductive liner film in the opening after performing the ion bombardment. A reflow process may be performed in forming the first conductive film, such that the first conductive film at least partially fills the opening.

In some embodiments, the ion bombardment may be performed using an ion source comprising argon (Ar), helium (He), neon (Ne), krypton (Kr), xenon (Xe), and/or radon (Rn).

In some embodiments, after performing the reflow process, the first conductive film may include a recess therein defining a bottom thickness of the first conductive film on the underlying conductive wiring layer that is greater than a sidewall thickness of the first conductive film on the sidewalls of the opening.

In some embodiments, a second conductive film may be formed on the first conductive film in the opening. The second conductive film may fill the recess of the first conductive film and may be free of a void therein.

In some embodiments, a plating process may be performed, using the first conductive film as a seed layer, in forming the second conductive film.

In some embodiments, the conductive liner film may include ruthenium (Ru).

In some embodiments, the conductive liner may have a substantially uniform thickness on the underlying conductive wiring and on the sidewalls of the opening in the interlayer insulating layer.

In some embodiment, the first and/or second conductive films may comprise copper (Cu).

In some embodiments, an anneal of the conductive liner film may be performed prior to performing the ion bombardment. The anneal may remove carbon-based impurities from the surface of the conductive liner film to increase an adhesion characteristic thereof.

In some embodiments, the anneal and the ion bombardment may be sequentially performed ex-situ. The anneal may be performed at a temperature of 150° C. to 250° C., and the ion bombardment may be performed at a temperature of 300° C. to 400° C.

In some embodiments, the ion bombardment and the reflow process may be sequentially performed in a same chamber in-situ.

According to some embodiments of the inventive concepts, a method of forming a wiring structure in a semiconductor device comprises forming a lower structure on a substrate, forming an interlayer insulating film including an opening on the lower structure, forming a liner film on an inner surface of the opening, treating a surface of the liner film by an ion bombardment, and forming a first conductive film on the liner film, the forming of the first conductive film is performed such that the first conductive film is at least partially filled in the opening through a reflow process.

The liner film may comprise ruthenium and is formed through a chemical vapor deposition (CVD) process.

The ion bombardment treatment may be performed by using an ion source including argon (Ar), helium (He), neon (Ne), krypton (Kr), xenon (Xe), radon (Rn), or combinations thereof through a plasma process.

The first conductive film may comprise copper (Cu) and is formed through the reflow process.

The method may further comprise forming a second conductive film through a plating process using the first conductive film as a seed layer.

The first conductive film may comprise copper (Cu) and is formed through the reflow process and wherein the second conductive film may comprise copper (Cu) and is formed through the plating process.

The first conductive film may be formed to partially fill a lower portion of the opening so as to define a recessed region in an upper portion of the opening, and the second conductive film may be formed to fill the recessed region.

A shortest distance between a bottom surface of the recessed region and a bottom of the opening may be greater than a shortest distance between a side surface of the recessed region and a side surface of the opening.

The method may further comprise, prior to treating the surface of the liner film by the ion bombardment, treating the surface of the liner film by an annealing process in an inert gas atmosphere.

The annealing may be performed at a temperature ranging from 150° C. to 250° C.

The ion bombardment may be performed at a temperature ranging from 300° C. to 400° C.

The annealing and the ion bombardment treatment may be sequentially performed ex-situ.

The ion bombardment treatment and the reflow process for forming the first conductive film may be performed in a same chamber in-situ.

The first conductive film may be formed to completely fill the opening.

The lower structure may be formed to include a lower insulating film and a lower wiring, and the lower wiring may be formed to be at least partially exposed by the opening.

The opening may be formed to include a via-hole that exposes the lower wiring and a trench that is connected to the via-hole in an upper portion of the interlayer insulating film.

The first conductive film may be formed to completely fill the via-hole and to extend on a sidewall and a bottom of the trench.

The method may further comprise forming a second conductive film filling the remaining portion of the trench, and the second conductive film may be formed to be grown from the first conductive film.

The method may further include forming an upper insulating film on the interlayer insulating film, the upper insulating film is formed to have a hole that is offset with respect to the via-hole and exposes a portion of the second conductive film formed in the trench, forming an upper liner film on an inner surface of the hole, treating a surface of the upper liner film by a subsequent ion bombardment, and forming an upper conductive film on the upper liner film, the upper conductive film is formed to at least partially fill the hole through a reflow process.

According to further embodiments of the inventive concepts, a method of forming a wiring structure in a semiconductor device comprises forming a lower structure on a substrate, forming an interlayer insulating film including an opening on the lower structure, conformally forming a liner film along an inner surface of the opening through a chemical vapor deposition (CVD) process, treating a surface of the liner film by an ion bombardment, forming a first metal film on the liner film through a reflow process, the first metal film is formed to include a first thickness measured from a bottom of the opening and a second thickness measured from a side surface of the opening less than the first thickness, and forming a second metal film through a plating process using the first metal film as a seed layer.

The method may further comprise, prior to treating the surface of the liner film by the ion bombardment, treating the surface of the liner film by an annealing process in a hydrogen atmosphere.

The ion bombardment may be performed such that a wettability of the surface of the liner film in a lower portion of the opening increases.

According to still further embodiments of the inventive concepts, a method of manufacturing a semiconductor device comprises forming a plurality of semiconductor fins on a substrate, forming a gate structure extending on the semiconductor fins, forming source/drain regions at an upper portion of the semiconductor fins adjacent to the gate structure, forming a contact being electrically in contact with at least one of the source/drain regions, forming an interlayer insulating film including an opening on the gate structure, the source/drain regions, and the contact, forming a liner film on an inner surface of the opening, treating a surface of the liner film by an ion bombardment, and forming a first conductive film on the liner film through a reflow process, the first conductive film may at least partially fill the opening.

The forming of the plurality of semiconductor fins on a substrate may comprise forming a channel film on the substrate, forming a device isolation film delimiting or defining an active region in the channel film, and recessing an upper portion of the device isolation film to expose an upper portion of the channel film.

The method may further comprise forming elevated source/drain (ESD) films on the source/drain regions, respectively.

The forming of the contact may comprise forming a lower insulating film on the gate structure and the source/drain regions, forming a contact hole exposing the source/drain region by partially removing the lower insulating film, and forming the contact in the contact hole, and the interlayer insulating film is formed on the lower insulating film.

The forming of the interlayer insulating film including an opening may comprise forming a first opening and a second opening by partially removing the interlayer insulating film, and the second opening may be formed to include a via-hole and a trench that is connected to the via-hole in an upper portion of the interlayer insulating film.

The first conductive film may be formed to completely fill the via-hole and to extend on a sidewall and a bottom of the trench.

The method may further include forming a second conductive film filling a remaining portion of the trench after forming the first conductive film to completely fill the via-hole and to extend on a side surface and a bottom surface of the trench.

The first conductive film may be formed to completely fill the first opening.

According to yet further embodiments of the inventive concepts, a wiring structure of a semiconductor device comprises an insulating film including an opening on a substrate, a liner film including ruthenium material on a bottom and a side surface of the opening, a reflowed metal film on the liner film, the reflowed metal film partially filling the opening and having a first thickness measured from the bottom of the opening and a second thickness measured from the side surface of the opening that is less than the first thickness, and a plating metal film on the metal film, the plating metal film filling a remaining portion of the opening.

The reflowed metal film and the plating metal film may comprise copper (Cu).

### BRIEF DESCRIPTION OF THE DRAWINGS

Example embodiments of the inventive concepts will be more clearly understood from the following detailed description taken in conjunction with the accompanying drawings. FIGS. 1 through 41 represent non-limiting, example embodiments as described therein.

FIG. 1 is a process flow chart illustrating methods of forming a wiring structure according to some embodiments of the inventive concepts.

FIGS. 2 through 10 are cross-sectional views illustrating methods of forming a wiring structure according to some embodiments of the inventive concepts.

FIGS. 11 through 13 are cross-sectional views illustrating methods of forming a wiring structure according to further embodiments of the inventive concepts.

FIGS. 14 and 15 are cross-sectional views illustrating methods of forming a wiring structure according to a comparative example.

FIGS. 16 through 25 are cross-sectional views illustrating methods of forming a wiring structure according to still further embodiments of the inventive concepts.

FIGS. 26 through 41 are perspective views and cross-sectional views illustrating methods of manufacturing a semiconductor device according to yet further embodiments of the inventive concepts.

### DETAILED DESCRIPTION

Hereinafter, example embodiments of the inventive concepts will be described with reference to the accompanying drawings. The inventive concepts may, however, be embodied in many different forms and should not be construed as being limited to the example embodiments set forth herein; rather, these example embodiments are provided so that this disclosure will be thorough and complete, and will fully convey the inventive concepts to those of ordinary skill in the art. It should be understood, however, that there is no intent to limit the inventive concepts to the particular forms disclosed, but on the contrary, the inventive concepts are to cover all modifications, equivalents, and alternatives falling within the spirit and scope of the inventive concepts. Like reference numerals denote like elements throughout the specification and drawings. In the drawings, the dimensions of structures are exaggerated or reduced for clarity of the inventive concepts.

Also, though terms “first” and “second” are used to describe various members, components, regions, layers, and/or portions in various example embodiments of the inventive concepts, the members, components, regions, layers, and/or portions are not limited to these terms. These terms are used only to differentiate one member, component, region, layer, or portion from another one. Therefore, a member, a component, a region, a layer, or a portion referred to as a first member, a first component, a first region, a first layer, or a first portion in an example embodiment may be referred to as a second member, a second component, a second region, a second layer, or a second portion in another example embodiment.

It will be understood that when an element is referred to as being “coupled” or “connected” to another element or layer, it can be directly coupled or directly connected to the other element or layer, or intervening elements or layers may also be present. In contrast, when an element is referred to as being directly coupled or directly connected to another element or layer, there are no intervening elements or layers present. As used herein, the term “and/or” includes any and all combinations of one or more of the associated listed items.

Spatially relative terms, such as “above,” “below,” “upper,” “lower,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Unless otherwise defined, all terms used herein, including technical and scientific terms, have the same meaning as commonly understood by one of ordinary skill in the art to which the inventive concepts belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

When a certain example embodiment may be implemented differently, a specific process or operation order may be performed differently from the described order. For example, two consecutively described processes or operations may be performed substantially at the same time or performed in an order opposite to the described order.

As used herein, the term “and/or” includes any and all combinations of one or more of the associated listed items. Expressions such as “at least one of,” when preceding a list of elements, modify the entire list of elements and do not modify the individual elements of the list.

Example embodiments of the inventive concepts will be described in detail with reference to the accompanying drawings.

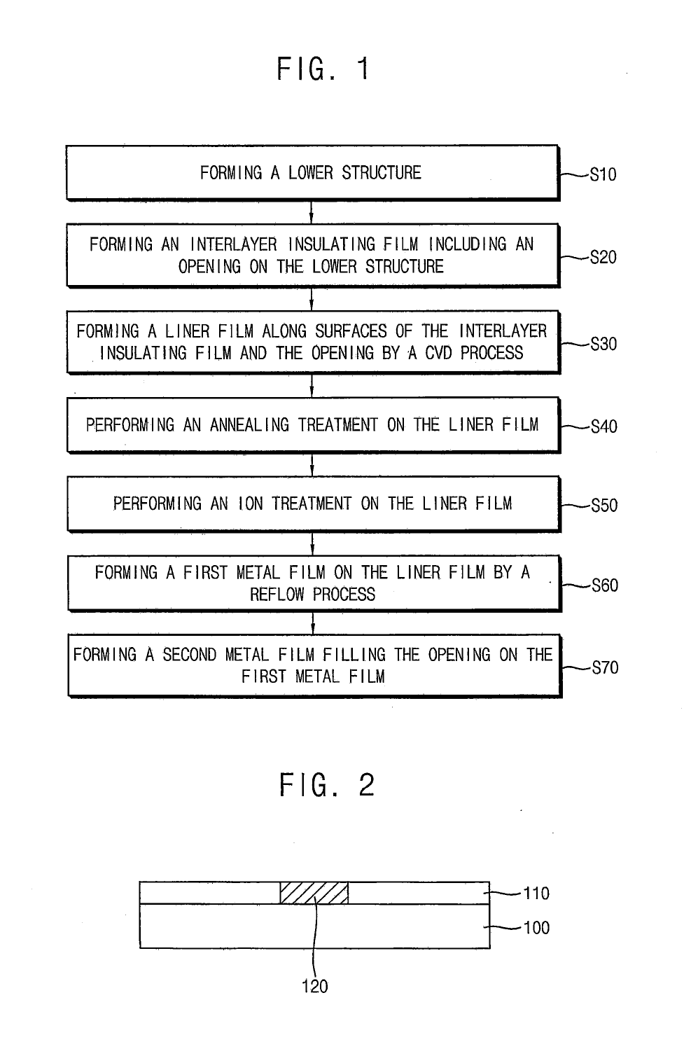

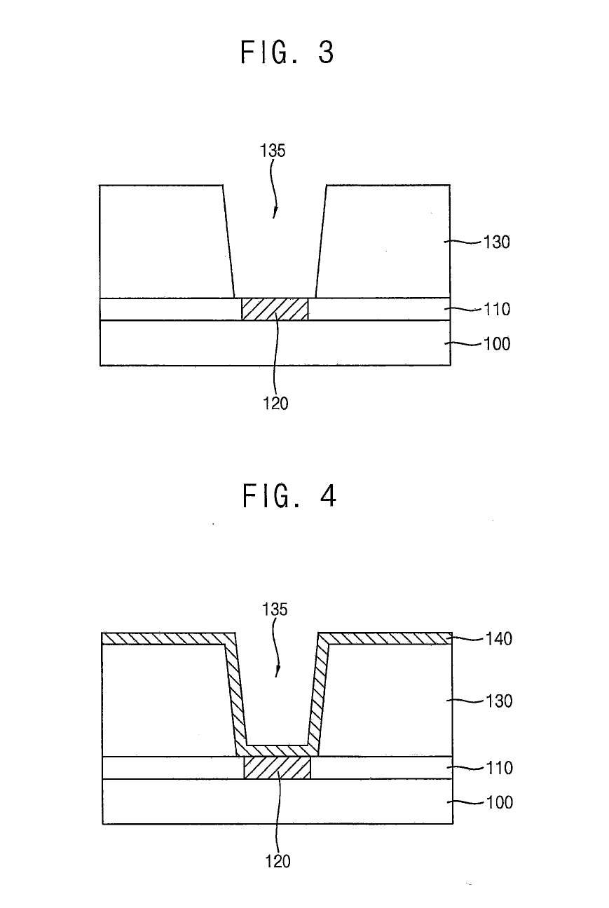

FIG. 1 is a process flow chart illustrating methods of forming a wiring structure according to some embodiments of the inventive concepts. FIGS. 2 through 10 are cross-sectional views illustrating methods of forming a wiring structure according to some embodiments of the inventive concepts.

Referring to FIGS. 1 and 2, for example, in operation S10, a lower structure that includes a lower insulating film 110 and a lower wiring 120 may be formed on a substrate 100. The substrate 100 may be a semiconductor substrate (e.g., a single crystal silicon substrate, a single crystal germanium substrate, etc.). Circuit elements (e.g., a gate structure, an impurity region, a contact, a plug, etc.) may be formed on the substrate 100.

The lower insulating film 110 may extend onto or cover the circuit elements. The lower insulating film 110 may be formed of an insulating material (e.g., silicon oxide, silicon oxynitride, etc.). For example, the lower insulating film 110 may include a silicon oxide-based material, for example, plasma enhanced oxide (PEOX), tetraethyl orthosilicate (TEOS), boro tetraethyl orthosilicate (BTEOS), phosphorous tetraethyl orthosilicate (PTEOS), boro phosphor tetraethyl orthosilicate (BPTEOS), boro silicate glass (BSG), phosphor silicate glass (PSG), boro phosphor silicate glass (BPSG), etc.

The lower insulating film 110 may be formed through at least one of a chemical vapor deposition (CVD) process, a plasma enhanced chemical vapor deposition (PECVD) process, a low pressure chemical vapor deposition (LPCVD) process, a high density plasma chemical vapor deposition (HDP-CVD) process, a spin coating process, a sputtering process, and an atomic layer deposition (ALD) process

In some embodiments, an etch stop layer (e.g., silicon nitride, etc.) may be further formed on the lower insulating film 110.

In some embodiments, after forming an opening (e.g., a hole, or a trench, etc.) by partially etching the lower insulating film 110, a conductive film that fills the opening may be formed on the lower insulating film 110 through a deposition process or a plating process. The lower wiring 120 may be formed by planarizing an upper portion of the conductive film through a chemical mechanical polishing (CMP) and/or an etch-back process. The lower wiring 120 may be electrically connected to the circuit elements that are formed on the substrate 100.

Referring to FIGS. 1 and 3, for example, in operation S20, an interlayer insulating film or layer 130 including an opening 135 may be formed on the lower structure.

In some embodiments, after forming a photoresist film on the interlayer insulating film 130, a photoresist pattern that exposes a portion of a top surface of the interlayer insulating film 130 by partially removing the photoresist film may be formed. The opening 135 may be formed by partially etching the interlayer insulating film 130 using the photoresist pattern as a mask.

The opening 135 may be substantially hole-shaped or trench-shaped. In some embodiments of the inventive concepts, the opening 135 may be provided as a via-hole. As shown in FIG. 3, a top surface of the lower wiring 120 may be entirely exposed through the opening 135. A top surface of the lower insulating film 110 may be partially exposed through the opening 135.

The interlayer insulating film 130 may include silicon oxide, silicon oxynitride, or a combination thereof and may be formed through a CVD process or a spin coating process. In some embodiments, after forming the opening 135, the photoresist pattern may be removed using an ashing process and/or a strip process.

Referring to FIGS. 1 and 4, for example, in operation S30, a liner film 140 may be formed along the top surface of the interlayer insulating film 130 and an inner surface of the opening 135.

In some embodiments, the liner film 140 may be formed using a metal precursor through a CVD process. For example, in the case where the opening 135 is a via-hole that is formed in a back-end-of-line (BEOL) process of highly integrated semiconductor devices, the opening 135 may have a critical dimension of a fine spacing and a fine pitch. For example, if the critical dimension decreases in scale close to about 10 nm, a physical vapor deposition (PVD) process (e.g., a sputtering process) or an ALD process having good vertical deposition characteristics may not be able to form the liner film 140 having an uniform profile on a side surface and a bottom surface of the opening 135.

Therefore, the liner film 140 may be formed through a CVD process having good horizontal deposition characteristics as well as good operation coverage characteristics.

In some embodiments, the liner film 140 may be formed using a ruthenium (Ru) precursor (i.e., ruthenium carbonyl). Therefore, the liner film 140 may be formed of ruthenium (Ru)-through a CVD process (i.e., it is referred to as CVD-Ru process). The ruthenium (Ru) may have better deposition characteristics through a CVD process than a metal (e.g., titanium, or tantalum, etc.). In addition, the ruthenium (Ru) may have a lower alloy forming characteristics than a metal (e.g., cobalt, etc.)

Accordingly, the liner film 140 having a uniform profile or thickness along the side surface and the bottom surface of the opening 135 may be formed using ruthenium (Ru) through a CVD process. In addition, the liner film 140 (e.g., ruthenium, etc.) may not react with a metal film formed in the opening 135 in a following process.

The liner film 140 may be provided as a barrier that reduces or prevents a conductive substance from diffusing into the interlayer insulating film 130, during a subsequent process for forming the metal film. In addition, the liner film 140 may provide a desired adhesion for forming the metal film.

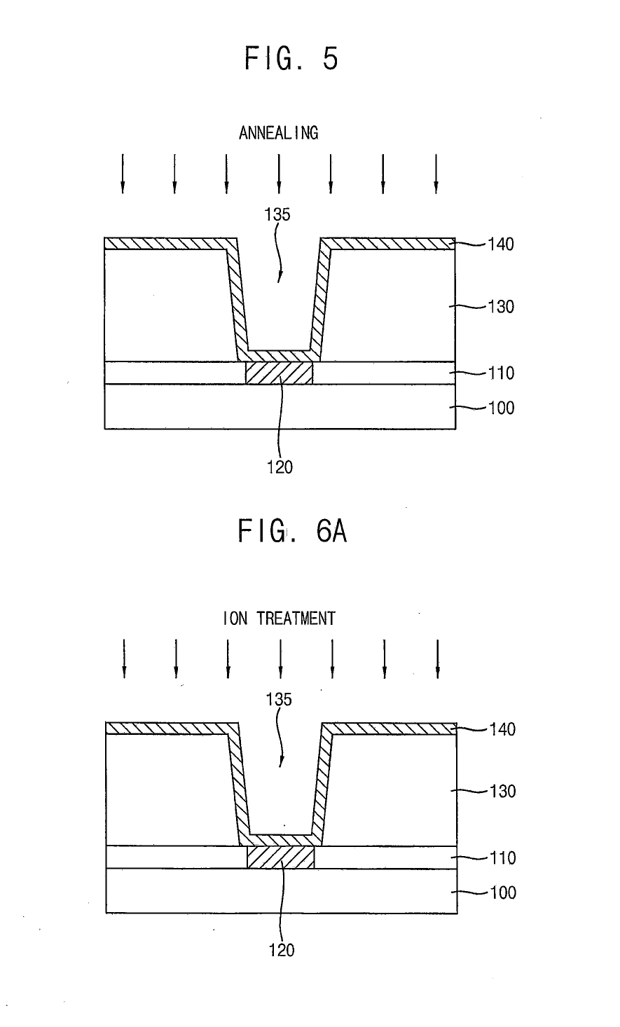

Referring to FIGS. 1 and 5, for example, in operation S40, a surface of the liner film 140 may be treated by annealing.

In some embodiments, the annealing treatment may be performed in a separate annealing chamber. For example, after forming the liner film 140 on the substrate 100, the substrate 100 is carried out from a CVD process chamber and is positioned on a hot plate arranged in the annealing chamber. In some embodiments of the inventive concepts, the surface of the liner film 140 may be annealed through the hot plate at the temperature ranging from about 150° C. to about 250° C.

In some embodiments, the annealing treatment may be performed in an inert gas atmosphere. For example, the annealing treatment may be performed such that the annealing chamber is maintained in a hydrogen (H2) atmosphere. Accordingly, since carbon-based impurities (e.g., carbonyl group) remaining on a surface of the liner film 140 are removed through the annealing treatment, surface characteristics of the liner film 140 for forming the metal film in a following process may be improved.

If the temperature of the annealing treatment is less than about 150° C., the impurities may not be sufficiently removed from the surface of the liner film 140. If the temperature of the annealing treatment is greater than about 250° C., the surface of the liner film 140 may be damaged and a defect may occur onto the surface of the liner film 140.

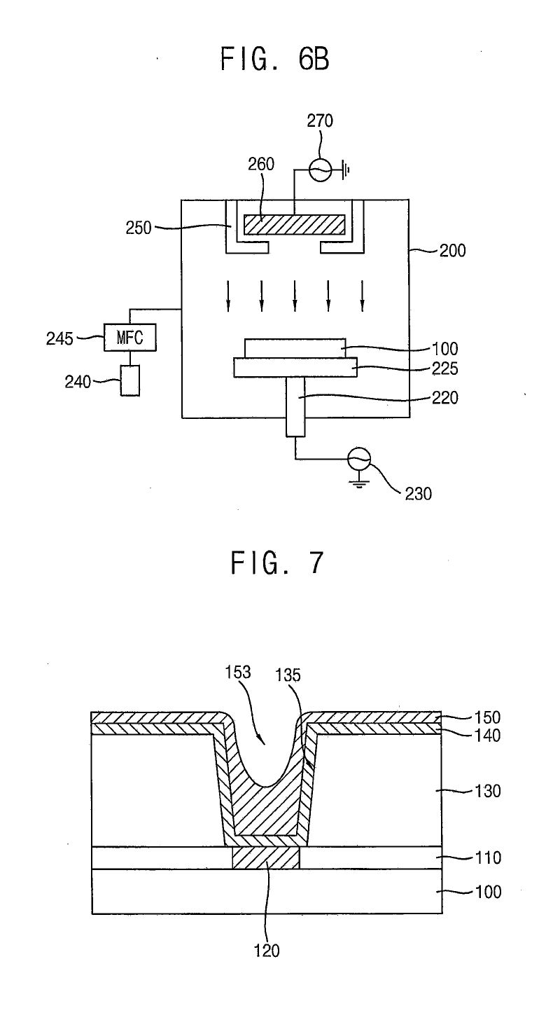

Referring to FIGS. 1, 6A, and 6B, for example, in operation S50, the surface of the liner film 140 may be treated by ions. The ion treatment may include an ion bombardment.

In some embodiments, the ion treatment may be sequentially performed with the above described annealing treatment ex-situ. For example, the ion treatment may be performed in a separate chamber 200 as illustrated in FIG. 6B. After performing the annealing treatment as described with reference to FIG. 5, the substrate 100 may be taken out from the annealing chamber and may be transferred to the inside of the chamber of FIG. 6B.

The substrate may be loaded on a rotatable support section 225. In some embodiments of the inventive concepts, a susceptor in which a plurality of slots is formed may be positioned on the support section 225. A plurality of substrates 100 may be positioned on the slots, respectively.

The support section 225 may be rotated in conjunction with a chuck 220. The chuck 220 may be positioned to pass through the chamber 200.

A bias power supply section 230 may be connected to the support section 225 through the chuck 220. Ions that are generated in the inside of the chamber 200 by applying a radio frequency (RF) bias power to the support section 225 from the bias power supply section 230 may be accelerated toward the substrate 100.

A reaction gas supply section 240 provide in the outer part of the chamber 200 may be connected to the chamber 200. Ion source may be introduced in the inside of the chamber 200 from the reaction gas supply section 240.

In some embodiments, a mass flow controller (MFC) 245 that is equipped between the reaction gas supply section 240 and the chamber 200 may control a supply amount of the ion source. The ion source may include argon (Ar), helium (He), neon (Ne), krypton (Kr), xenon (Xe), radon (Rn), or combinations thereof.

In some embodiments, a plasma process may be performed such that plasma is formed from the ion source as a reaction gas by, applying a predetermined power to the inside of the chamber. For example, the reaction gas (i.e., ion source) may be converted to ions (e.g., argon ion Ar³⁰ ). As described above, the surface of the liner film 140 may be treated through the ion bombardment using the ions that are accelerated toward the substrate 100.

Through the ion bombardment treatment, the profile of the liner film 140 may be uniform and impurities may be additionally removed from the liner film 140. In addition, a wettability of the liner film 140 that is formed on the bottom surface of the opening 135 may be improved. Accordingly, a metal film that is formed in a subsequent process may be easily guided into the inside of the opening 135.

In some embodiments, the ion bombardment treatment may be performed at a temperature ranging from about 300° C. to about 400° C. If the temperature of the ion bombardment treatment is less than about 300° C., the amount of the ions may not be sufficient. If the temperature of the ion bombardment treatment is greater than about 400° C., the surface of the liner film 140 may be damaged.

In some embodiments, a metallic target 260 may be supported by a shield 250 at a top of the chamber 200. The metallic target 260 may be connected to the RF power supply section 270.

Referring to FIGS. 1 and 7, for example, in operation S60, a first metal film 150 may be formed on the liner film 140 to be partially filled in a lower portion of the opening 135. The first metal film 150 may have a recessed region 153 in an upper portion of the opening 135.

In some embodiments, the first metal film 150 may be formed through a reflow process. The reflow process may be performed in the same chamber 200 as the ion bombardment treatment described with reference to FIGS. 6A and 6B. The reflow process may be performed with the ion bombardment treatment in-situ.

After completing the ion bombardment treatment, a high frequency power may be applied to the metallic target 260 through the RF supply section 270. A metallic material separated from the metallic target may move towards the substrate 100 and may be deposited on the liner film 140 that is formed on the substrate 100. For example, by supplying a reaction gas (i.e., ion source) through the reaction gas supply section 240 and applying a predetermined power through the bias power supply section 230, the metallic material may be guided towards the liner film 140.

In some embodiments, the metallic target may be formed of copper (Cu). In this case, the first metal film 150 may include copper (Cu).

As described above, through the ion bombardment treatment, the liner film 140 may have improved surface characteristics that are suitable to the subsequent reflow process. For example, in the subsequent reflow process, the copper (Cu) for forming the first metal film 150 may be sufficiently reflowed in the inside of the opening 135 through improving wettability characteristics and/or adhesion characteristics of the liner film 140 adjacent to the bottom surface of the opening 135. The metallic material may be reflowed in the inside of the opening 135 without an agglomeration or an excessive stay on the top surface of the interlayer insulating film 130. In other words, the first metal film 150 may be formed relatively thin on a portion of the liner film 140 adjacent to the top surface of the interlayer insulating film 130 and may be deposited thickly in the inside of the opening 135. Therefore, the first metal film 150 may have an inner surface delimiting or defining the recessed region 153 in the upper portion of the opening 135.

In some embodiments, the shortest distance between a bottom surface of the recessed region 153 and the bottom surface of the opening 135 may be greater than the shortest distance between a side surface of the recessed region 153 and the side surface of the opening 135.

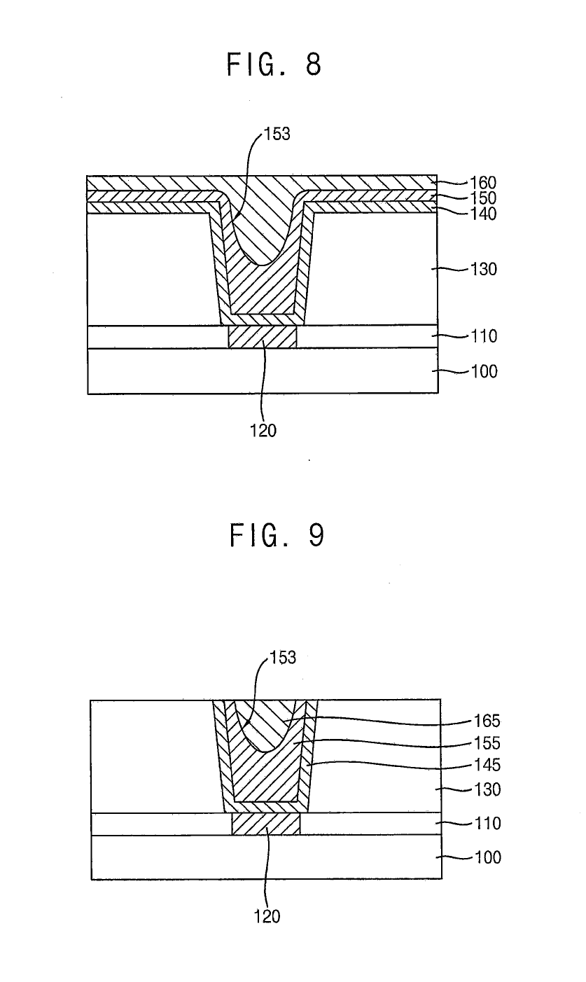

Referring to FIGS. 1 and 8, for example, in operation S70, a second metal film 160 may be formed on the first metal film 150. The second metal film 160 may be completely filled in the recessed region 153.

In some embodiments, the second metal film 160 may be formed through a plating process using the first metal film 150 as a seed layer. For example, the second metal film 160 may be formed through an electroplating process using copper (Cu). In this case, after the substrate on which the first metal film 160 is formed is immersed in a plating solution including copper sulfate, a current may be applied using the first metal film 150 as a cathode and the plating solution as an anode. Accordingly, the second metal film 160 (e.g., copper, etc.) may be formed on the first metal film 150 by an electrochemical reaction.

As described above, since the first metal film 150 is sufficiently reflowed in the inside of the opening 135, the bottom surface of the recessed region 153 may be at a level spaced sufficiently apart from the bottom surface of the opening 135. For example, the bottom surface of the recessed region 153 may be at a level higher than half the depth of the opening 135. The second metal film 160 may completely fill the recessed region 153 and extend onto or cover a portion of the first metal film 150 extending onto the top surface of the interlayer insulating film 130.

Referring to FIG. 9, the second metal film 160, the first metal film 150, and the liner film 140 may be planarized through a CMP process and/or an etch-back process until the top surface of the interlayer insulating film 130 is exposed. Accordingly, a wiring structure that is electrically connected to the lower wiring 120 may be formed in the inside of the opening 135. The wiring structure may include a liner film pattern 145, a first metal film pattern 155 (i.e., a reflowed metal film pattern), and a second metal film pattern 165 (i.e., a plating metal film pattern) that are sequentially stacked the inner surface of the opening 135. The wiring structure may function as an interconnection structure (e.g., a via-structure, etc.) in which the lower wiring 120 is electrically connected to an upper wiring. Here, the first metal film pattern 155 may have a first thickness that is measured from the bottom of the opening 135 and a second thickness that is measured from the side surface of the opening 135 less than the first thickness.

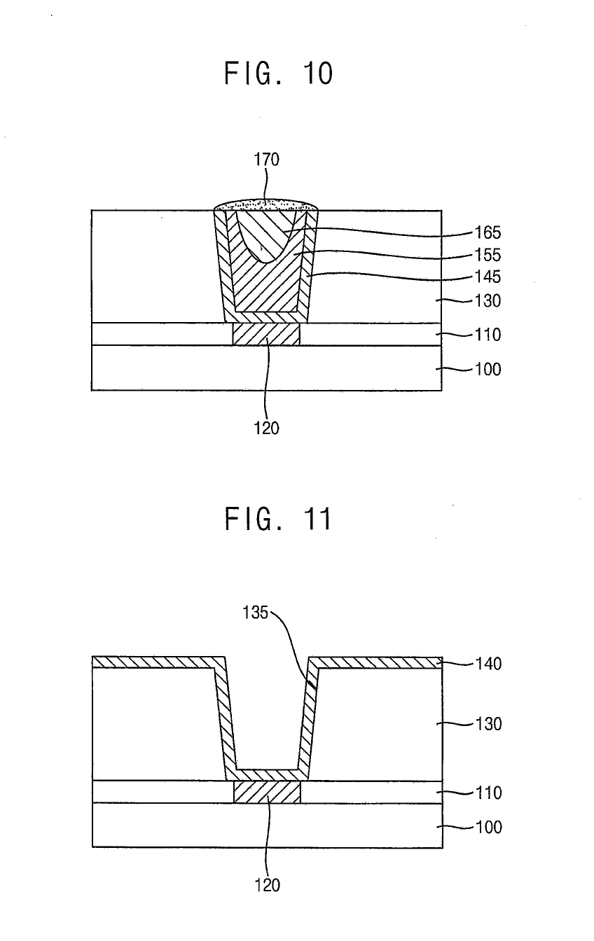

Referring FIG. 10, a capping film 170 may be further formed to extend onto or cover a top surface of the wiring structure. The capping film 170 may connect to top surfaces of the liner film pattern 145, the first metal film 155, and the second metal film pattern 165.

The capping film 170 may be formed through a sputtering process or an ALD process using a metal more chemically stable than the metal contained in the liner film pattern 145, the first metal film pattern 155, and the second metal film pattern 165. For example, the capping film 170 may include aluminum, cobalt, or molybdenum, etc. In some embodiments of the inventive concepts, the capping film 170 may be formed of a metal nitride.

In some embodiments, the capping film 170 may be formed in a substantially self-aligned manner on top surface of the wiring structure by an affinity between a metallic material contained in the capping film 170 and respective metallic materials contained in the liner film pattern 145, the first metal film 155, and the second metal film pattern 165. Accordingly, the capping film 170 may be formed to extend onto or cover the top surface of the wiring structure without performing another etching process.

In some embodiments, the top surface of the capping film 170 may have substantially a curved shape or a dome shape.

According to the above-described example embodiments of the inventive concepts, the liner film 140 may be formed to have an entirely uniform profile in the inside of the opening 135 through the CVD-Ru process. Through treating the surface of the liner film 140 by the ion bombardment, the reflow characteristics of the surface of the liner film 140 may be improved. Therefore, since a seed layer including a metal (e.g., copper, etc.) is sufficiently filled in the inside of the opening 135, a highly reliable wiring structure in which a defect (e.g., a void, a seam, etc.) is prevented or removed through the subsequent plating process may be formed.

FIGS. 11 through 13 are cross-sectional views illustrating methods of forming a wiring structure according to further embodiments of the inventive concepts. A detailed description of the processes and/or the materials being substantially the same as or similar to those described with reference to FIGS. 1 through 10 will be omitted. In addition, the same reference numerals are used for substantially the same configuration.

Referring to FIG. 11, the processes substantially the same as or similar to those described with reference to FIGS. 2 through 5, 6A, and 6B may be performed.

For example, the lower structure including the lower insulating film 110 and the lower wiring 120 may be formed on the substrate 100. The interlayer insulating film 130 having the opening 135 that exposes the lower wiring 120 in the lower insulating film 110 may be formed. The liner film 140 may be uniformly formed along the top surface of the interlayer insulating film 130 and the inner surface of the opening 135. The liner film 140 may contact the lower wiring 120. The liner film 140 may be formed through a CVD-Ru process, for example.

As described above, the surface of the liner film 140 may be treated by an annealing process in a hydrogen atmosphere and by an ion bombardment.

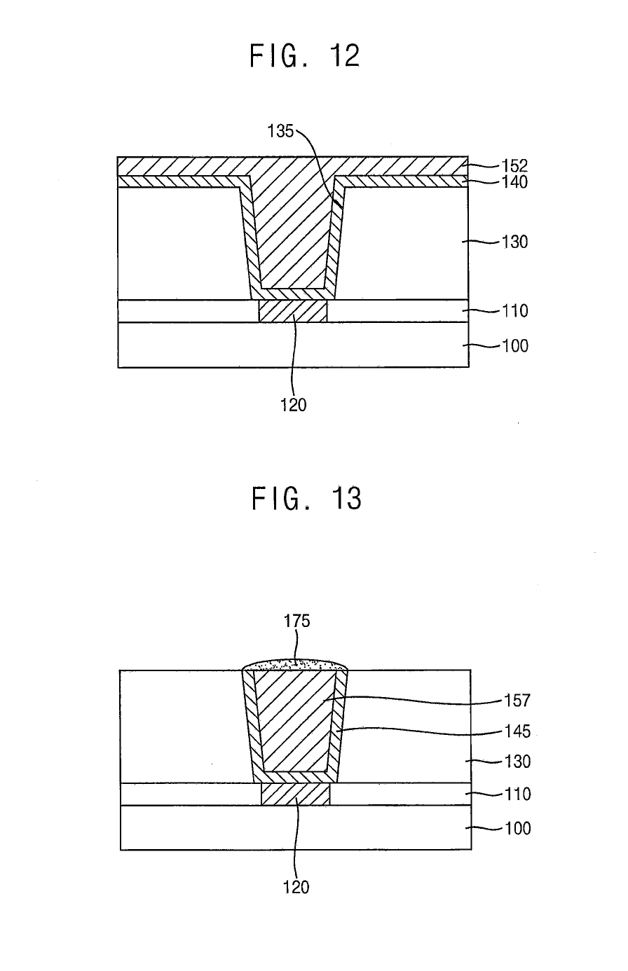

Referring to FIG. 12, a first metal film 152 may be formed on the liner film 140 through a copper reflow process.

In some embodiments, the first metal film 152 may be completely filled in the opening 135. Since the liner film 140 has improved wettability and adhesion characteristics in the inside of the opening 140 by the ion bombardment treatment, even though a width or a critical dimension of the opening 135 is reduced, the opening 135 may be completely filled with only the first metal film 152.

Referring to FIG. 13, respective upper portions of the first metal film 152 and the liner film 140 may be planarized through a CMP process and/or an etch-back process. Accordingly, a wiring structure that includes a liner film pattern 145 and a first metal film pattern 157 may be formed. As described with reference to FIG. 10, a capping film 175 may be formed on the wiring structure. The capping film 175 may contact the liner film pattern 145 and the first metal film pattern 157 and may be electrically in contact with the lower wiring 120.

According to the above-described example embodiments of the inventive concepts, since surface characteristics of the liner film 140 is improved through the ion bombardment treatment, the wiring structure may be formed through only the reflow process without an additional plating process.

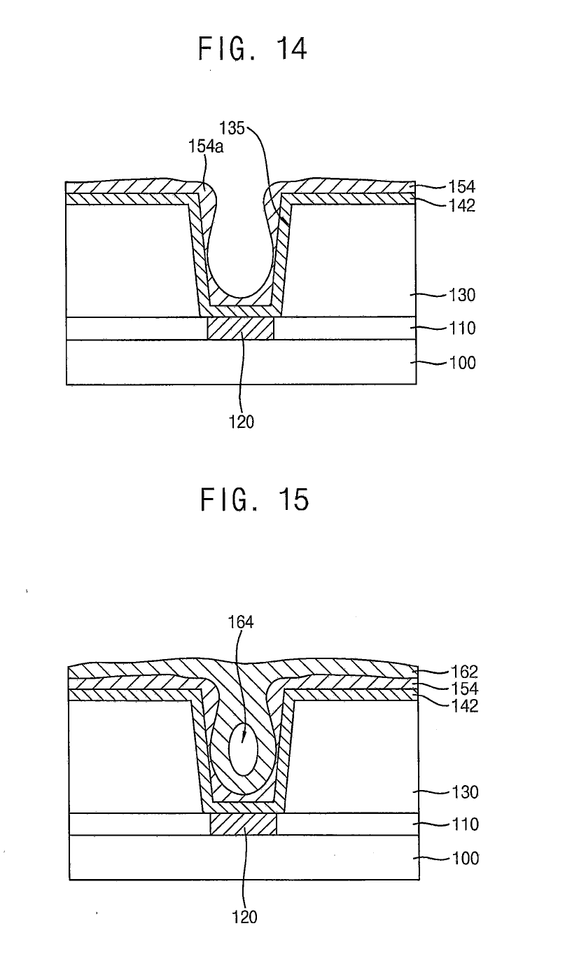

FIGS. 14 and 15 are cross-sectional views illustrating methods of forming a wiring structure according to a comparative example.

Referring to FIG. 14, as described with reference to FIGS. 2 and 3, the lower structure that includes the lower insulating film 110 and the lower wiring 120 may be formed on the substrate 100. The interlayer insulating film 130 that includes the opening 135 may be formed on the lower structure. A liner film 142 may be formed along the top surface of the interlayer insulating film 130 and the inner surface of the opening 135 through the CVD-Ru process.

Without the annealing treatment and/or the ion bombardment treatment, if the above-described copper reflow process is performed on the liner film 142, a surface wettability of the liner film 142 in the inside of the opening 135 may be not ensured. Therefore, a first metal film 154 that is formed in a following process may not sufficiently fill the inside of the opening 135. Accordingly, a protrusion portion 154a of the first metal film 154 may be formed on the liner film 142 in the vicinity of an entrance of the opening 135.

Referring to FIG. 15, a second metal film 162 for the wiring structure may be formed on the first metal film 154 through a plating process. As illustrated in FIG. 14, since the first metal film 154 that acts as a seed layer is not sufficiently filled in the inside of the opening 135 and the protrusion portion 154a of the first metal film 154 is formed in the vicinity of the entrance of opening 135, a void 164 may be formed in the second metal film 162 in the inside of the opening 135.

However, according to the above-described example embodiments of the inventive concepts, prior to forming the first metal film, through treating the surface of the liner film by the ion bombardment, the wettability and the adhesion characteristics of the liner film may be improved and thereby sufficiently filling the first metal film in the inside of the opening. Accordingly, a wiring structure in which a defect (e.g., a void, etc.) is prevented or removed in the inside of the opening may be formed.

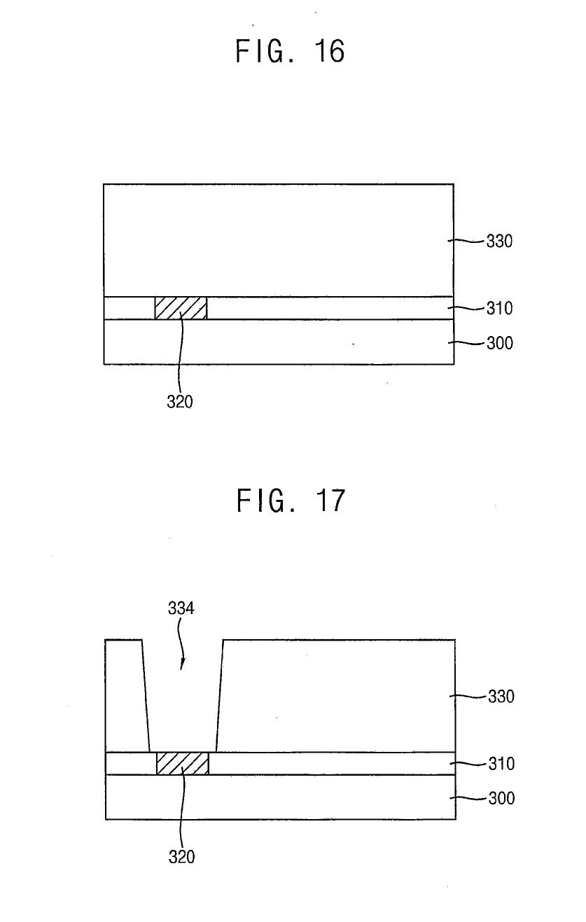

FIGS. 16 through 25 are cross-sectional views illustrating methods of forming a wiring structure according to still further embodiments of the inventive concepts. A detailed description of the processes and/or the materials substantially the same as or similar to those described with reference to FIGS. 1 through 10 will be omitted.

Referring to FIG. 16, as described with reference to FIG. 2, a lower insulating film 310 and a lower wiring 320 may be formed on a substrate 300. A first interlayer insulating film 330 may be formed on the lower insulating film 310 and the lower wiring 320 using a silicon oxide-based material.

Referring to FIG. 17, through the process being substantially the same as or similar to that described with reference to FIG. 3, a via-hole 334 may be formed by partially removing the first interlayer insulating film 330. A top surface of the lower wiring 320 may be at least partially exposed through the via-hole 334.

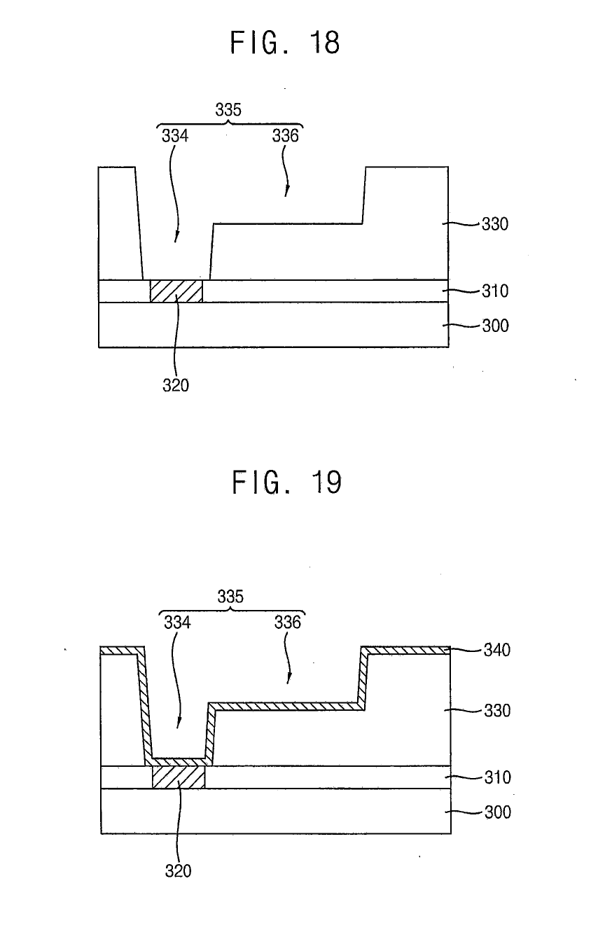

Referring to FIG. 18, a trench 336 that is connected to the via-hole 334 may be formed by removing a top portion of the first interlayer insulating film 330. For example, the trench 336 may be partially overlapped with the via-hole 334 and may have a line shape extending in a direction. Accordingly, a first opening 335 that includes the via-hole 334 and the trench 336 may be formed through a double damascene process.

Referring to FIG. 19, the process being substantially the same as or similar to that described with reference to FIG. 4 may be performed. For example, a liner film 340 that has a substantially uniform thickness may be formed along a top surface of the first interlayer insulating film 330 and an inner surface (i.e., a side surface and a bottom surface) of the first opening 335 through a CVD-Ru process.

In some embodiments of the inventive concepts, the process being substantially the same as or similar to that described with reference to FIG. 5 may be further performed. For example, a top surface of the liner film 340 may be treated by an annealing process in a hydrogen atmosphere. Accordingly, the top surface of the liner film 340 may be substantially cleaned, thereby to improve adhesion characteristics of the liner film 340.

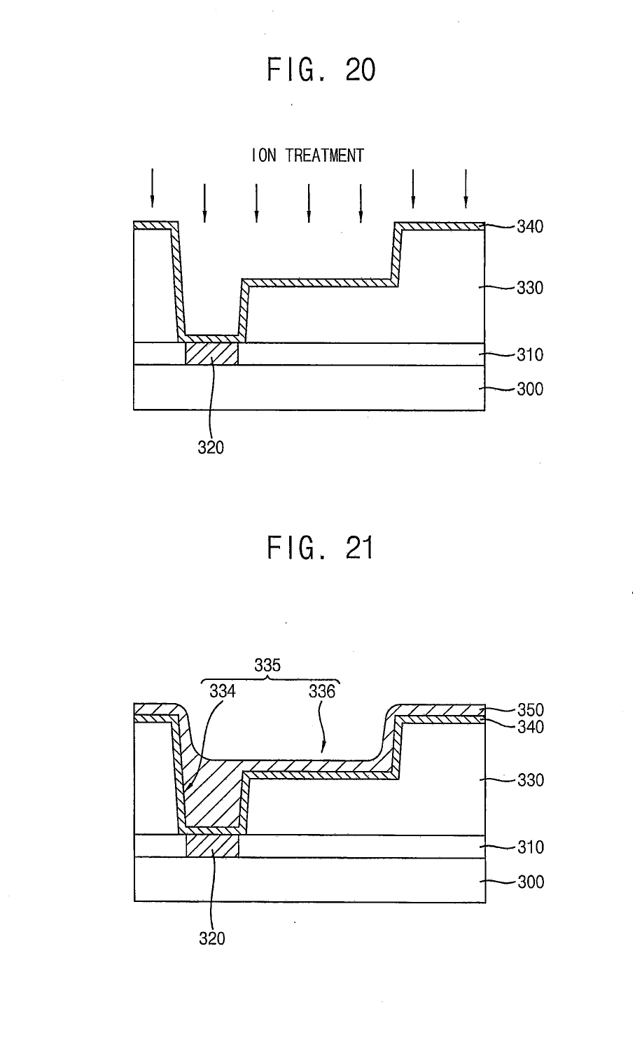

Referring to FIG. 20, the process being substantially the same as or similar to that described with reference to FIGS. 6A and 6B may be performed. The surface of the liner film 340 may be treated by an ion bombardment. For example, the substrate 300 may be transferred from the annealing chamber to a separate ion bombardment treatment chamber. An ion source including an inert gas (e.g., Ar, Ne, Kr, Xe, etc.) may be converted to ions using a plasma process. By impacting the surface of the liner film 340 with the ions, reflow characteristics of the liner film 340 in the inside of the first opening 335 may be improved.

Referring to FIG. 21, the process being substantially the same as or similar to that described with reference to FIG. 7 may be performed. For example, a first metal film 350 may be formed on the liner film 340 through a copper reflow process. Since one or more surface characteristics (e.g., wettability, etc.) of the liner film 340 in the inside of the first opening 335 are improved through the ion bombardment treatment, the first metal film 350 may be sufficiently filled in the via-hole 334.

In some embodiments, the first metal film 350 may completely fill the via-hole 334 and may be formed to have a relatively thin thickness on the liner film 340 that is formed on an inner surface (i.e., a side surface and a bottom surface) of the trench 336 and the first interlayer insulation film 330.

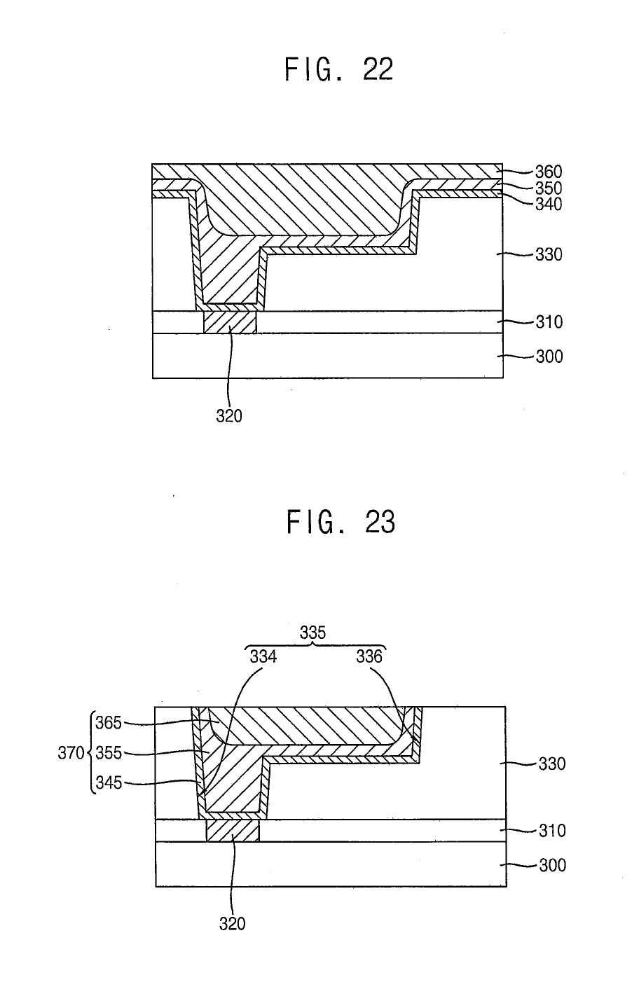

Referring to FIG. 22, though the process being substantially the same as or similar to that described with reference to FIG. 8, a second metal film 360 may be formed to fill the remaining portion of the first opening 335. For example, the second metal film 360 may be formed through a copper electroplating process that uses the first metal film 350 as a seed layer. Since the first metal film 350 is formed to be sufficiently filled in the via-hole 334, the seed layer for forming the second metal film 360 may be sufficiently ensured. Therefore, the second metal film 360 may be formed to completely fill the first opening 335 without defects (e.g., voids, etc.) in the trench 336.

Referring to FIG. 23, the process being substantially the same as or similar to that described with reference to FIG. 9 may be performed. For example, respective top portions of the second metal film 360, the first metal film 350, and the liner film 340 may be planarized through a CMP process and/or an etch-back process until a top surface of the interlayer insulating film 330 is exposed. Accordingly, a wiring structure 370 including a liner film pattern 345, a first metal pattern 355, and a second metal pattern 365 that are sequentially formed in the first opening 335 may be formed.

In some embodiments, as illustrated in FIG. 23, the first metal film pattern 355 may completely fill the via-hole 334 and partially fill the trench 336. The second metal film pattern 365 may fill the remaining portion of the trench 336.

As described with reference to FIG. 10, a capping film may further be formed to extend onto or cover a top surface of the wiring structure 370.

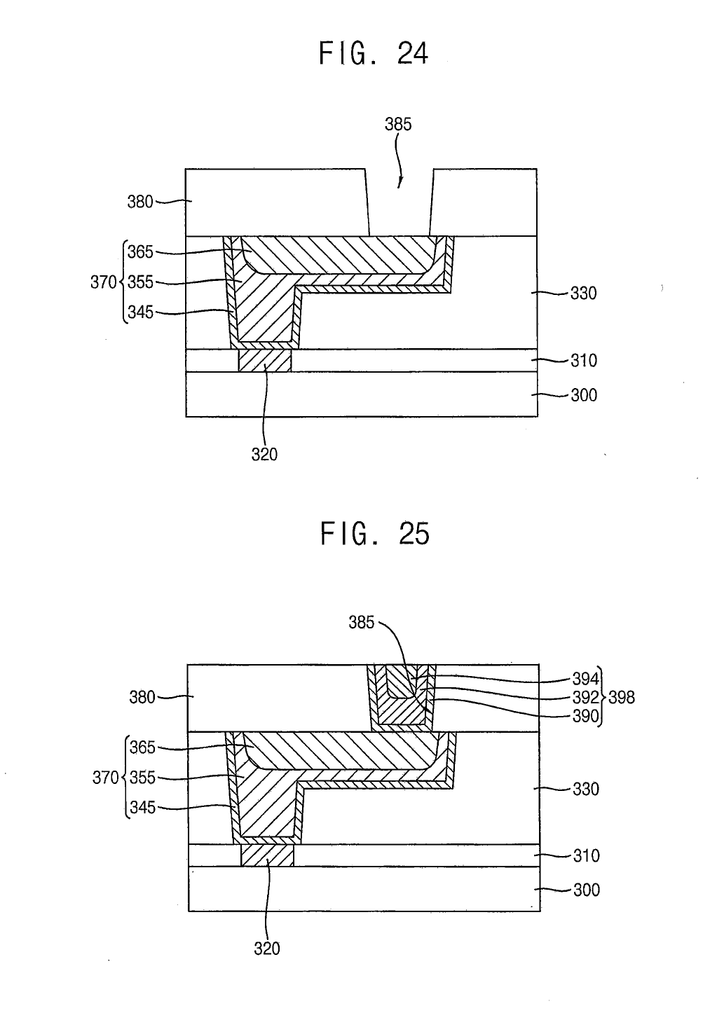

In some embodiments, an additional build-up process may further be performed on the wiring structure 370. For example, as illustrated in FIGS. 24 and 25, an upper wiring may be formed to be electrically connected to the wiring structure 370.

Referring to FIG. 24, a second interlayer insulating film 380 may be formed on the first interlayer insulating film 330 and the wiring structure 370. A second opening 385 that partially exposes the top surface of the wiring structure 370 may be formed by partially removing the second interlayer insulating film 380

The second opening 385 may be substantially hole-shaped. In some embodiments, the second opening 385 may not be overlapped with the via-hole 334 and may be vertically offset with respect to the via-hole 334. For example, the second opening 385 may be positioned on an extension portion of the trench 336 that is branched from the via-hole 334.

Referring to FIG. 25, the processes being substantially the same as or similar to those described with reference to FIGS. 4 through 9 may be performed. For example, an upper liner film may be formed along a top surface of the second interlayer insulating film 380 and an inner surface (i.e., a side surface and a bottom surface) of the second opening 385 through a CVD-Ru process. A surface of the upper liner film may be treated by a subsequent annealing process and ion bombardment. Next, a first upper metal film may be formed on the upper liner film through a copper reflow process and a second upper metal film may be formed to fill the remaining portion of the second opening 385 through a copper plating process from the first metal film. Respective top portions of the second upper metal film, the first upper metal film, and the upper liner film may be planarized through a CMP process and/or an etch-back process, thereby to form an upper wiring 398 in the second opening 385 that is electrically connected to the wiring structure 370.

The upper wiring 398 may include an upper liner film pattern 390, a first upper metal film pattern 392, and a second upper metal film pattern 394 that are sequentially stacked on the inner surface of the second opening 385.

As described with reference to FIG. 10, a capping film may further be formed to extend onto or cover a top surface of the upper wiring 398. The capping film may contact respective top surfaces of the upper liner film pattern 390, the first upper metal film pattern 392, and the second upper metal film pattern 394.

In some embodiments, as described with reference to FIGS. 12 and 13, since the first upper metal film is sufficiently reflowed in the inside of the second opening 385, only the first upper metal film may completely fill the second opening 385. In this case, the upper wiring 398 may be defined by the upper liner film pattern 390 and the first upper metal film pattern 392, and the second upper metal film pattern 394 may be omitted.

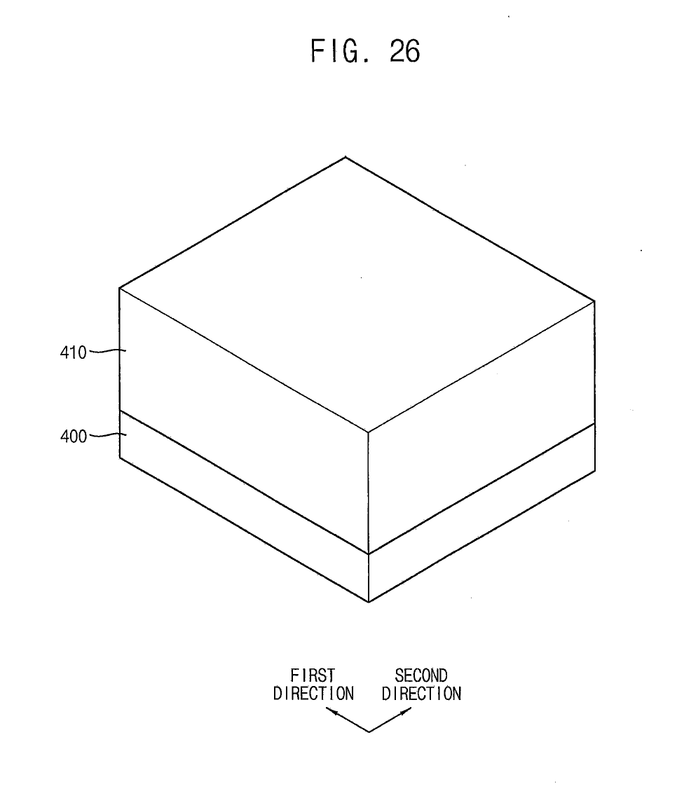

FIGS. 26 through 41 are perspective views and cross-sectional views illustrating methods of manufacturing a semiconductor device according to yet further embodiments of the inventive concepts. FIGS. 26 through 41 illustrate methods of manufacturing a semiconductor device including a fin-field effect transistor (FinFET).

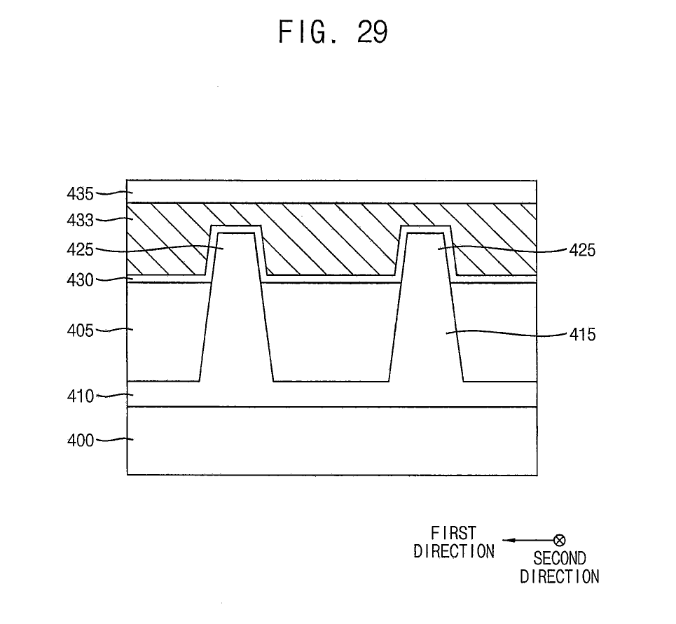

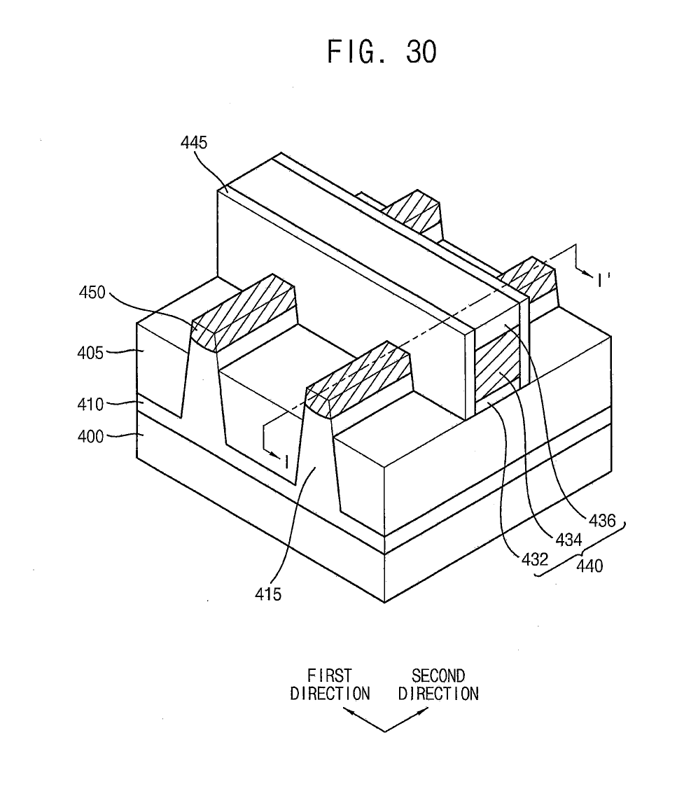

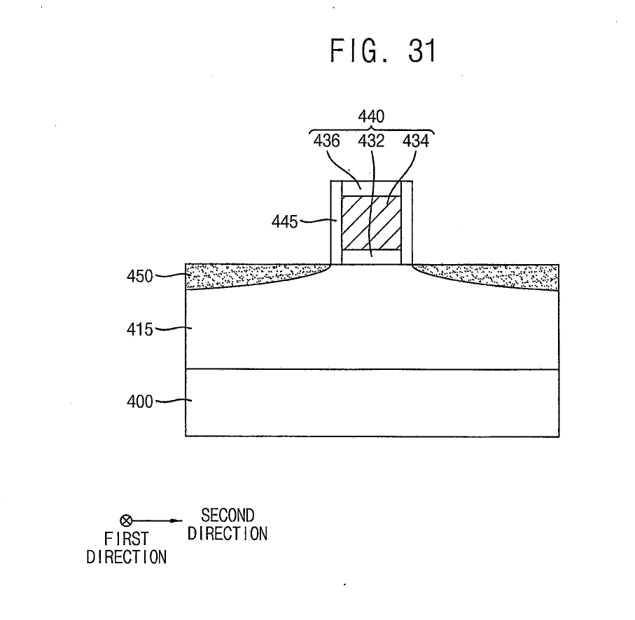

Specifically, FIGS. 26 through 28, 30, 32, and 34 are cross-sectional views illustrating methods of manufacturing the semiconductor device. FIG. 29 is a cross-sectional view taken along a first direction. FIGS. 31, 33, and 35 through 41 are cross-sectional views taken in a second direction along a line I-I′ depicted in FIGS. 30, 32, and 34. In FIGS. 26 through 41, the first direction and the second direction may be parallel to a top surface of the substrate and may intersect substantially perpendicular to each other. The directions indicated by arrows on the drawing and the opposite directions thereto are described as the same directions. However, a detailed description of the processes and/or the materials being substantially the same as or similar to those described with reference to FIGS. 1 through 10, 16 through 23 will be omitted.

Referring to FIG. 26, a channel film 410 may be formed on a substrate 400. The substrate 400 may include a semiconductor material (e.g., silicon, etc.). In some embodiments, the substrate 400 may be a silicon-on-insulator (SOI) substrate, or a germanium-on-insulator (GOI) substrate. The channel film 410 may include silicon containing a stress-applied element. For example, the channel film 410 may include silicon-germanium (Si-Ge). The channel film 410 may be formed through a selective epitaxial growth (SEG). For example, a silicon source gas and a germanium source gas may be provided on the substrate 400. Accordingly, the channel film 410 that includes the silicon-germanium may be formed from a top portion of the substrate 400 functioning as a seed layer.

For example, the silicon source gas may include silane (SiH₄), and/or di-chlorosilane (SiH₂Cl₂). The germanium source gas may include germanium tetrahydride (GeH₄), and/or germanium tetrachloride (GeCl₄).

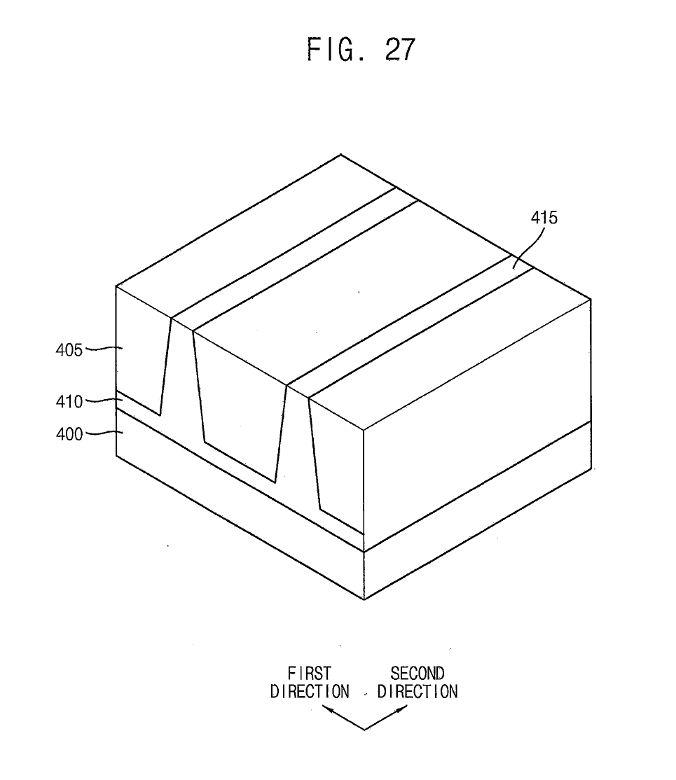

Referring to FIG. 27, a device isolation film 405 may be formed to delimit or define an active pattern 415 (i.e., an active region) in the channel film 410.

The device isolation film 405 may be formed through a shallow trench isolation (STI) process. For example, after forming a trench by partially removing the channel film 410, an insulating film may be formed on the channel film 410 to completely fill the trench. The device isolation film 405 may be formed by planarizing a top portion of the insulating film using a CMP process and/or an etch-back process until a top surface of the channel film 410 is exposed. The insulating film may include silicon nitride.

By forming the device isolation film 405, a plurality of fin-shaped protrusion portions from the channel film 410 may be formed and may be defined as the active patterns 415 (i.e., active regions). Each of the active patterns 415 may have a line shape extending in the second direction. In some embodiments, a well region may be formed on upper portions of the active patterns 415 through an ion implantation process.

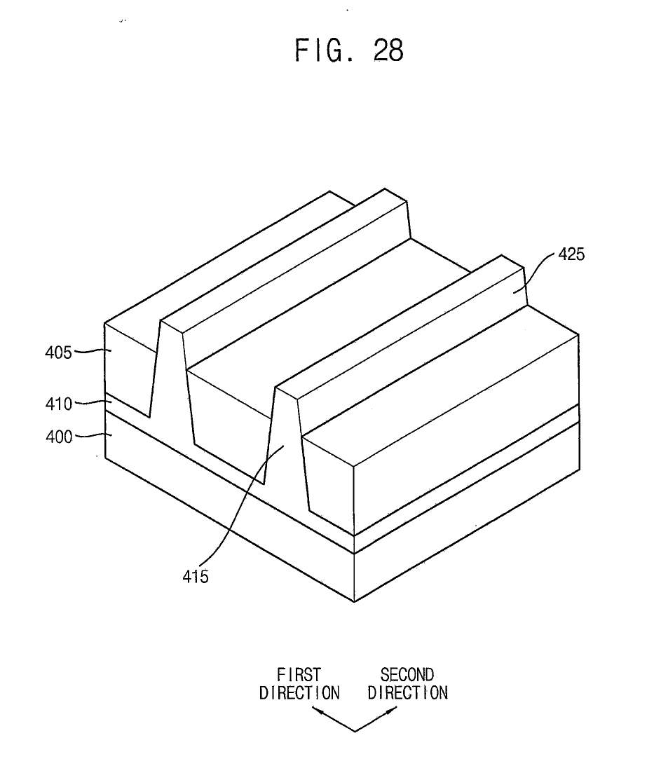

Referring to FIG. 28, the upper portions of the active pattern 415 may be exposed by removing or recessing an upper portion of the device isolation film 405 through an etch-back process. Each of the exposed upper portions of the active patterns 415 may define a semiconductor fin. The semiconductor fin may extend in the second direction and the plurality of the semiconductor fins may be arranged in the first direction.

Referring to FIG. 29, a gate dielectric film 430 may be formed on the device isolation film 405 to extend onto or cover one or more of the semiconductor fins 425. A gate electrode film 433 and a gate mask film 435 may be sequentially formed on the gate dielectric film 430.

The gate dielectric film 430 may be conformally deposited with a thin thickness along a top surface of the device isolation film 405 and a surface of the semiconductor fin 425. In some embodiments, the gate dielectric film 430 may be formed by thermally oxidizing the surface of the semiconductor fin 425. In this case, the gate dielectric film 430 may be formed on each semiconductor fin 425 in the form of respective patterns separated by the device isolation film 405.

The gate dielectric film 430 may be formed of silicon oxide and/or a metal oxide. The gate electrode film 433 may include poly-silicon, a metal, a metal nitride, a metal silicide, or a combination thereof. The gate mask film 435 may be formed of a silicon nitride. The gate dielectric film 430, the gate electrode film 433, and the gate mask film 435 may be formed through a CVD process, a PVD process, and/or an ALD process.

Referring to FIGS. 30 and 31, a gate mask 436 that extends in the first direction may be formed by patterning the gate mask film 435. By partially removing the gate electrode film 433 and the gate dielectric film 430 using the gate mask 436 as an etch mask, a gate electrode 434 and a gate dielectric film pattern 432 may be formed. Accordingly, a gate structure 440 including the gate dielectric film pattern 432, the gate electrode 434, and the gate mask 436 that extend in the first direction and are sequentially stacked on the device isolation film 405 and/or the semiconductor fins 425 may be formed. The gate structure 440 may extend across the plurality of the semiconductor fins 425 protruding from the top surface of the device isolation film 405. FIGS. 30 and 31 illustrate one gate structure 440, but a plurality of gate structures 440 may be formed, separated along the second direction.

A gate spacer 445 may further be formed on sidewalls of the gate structure 440. For example, a spacer film (e.g., silicon nitride, etc.) may be formed to extend onto or cover the device isolation film 405, the semiconductor fins 425, and the gate structure 440. The gate spacer 445 may be formed to extend onto or cover the sidewalls of the gate structure 440 by anisotropically etching the spacer film.

In some embodiments, the gate structure 440 may be formed through a damascene process. For example, a dummy pattern may be formed to extend in the first direction across the semiconductor fins 425, and the gate spacer 445 may be formed on sidewalls of the dummy pattern. An opening may be formed by removing the dummy pattern, and the gate structure 440 may be formed by sequentially stacking a gate dielectric film, a gate electrode film, and a gate mask film in the opening.

An ion implantation process may be performed into an upper portion of the exposed semiconductor fin 425 using the gate structure as an ion implantation mask. Therefore, first source/drain regions 450 may be formed in the upper portion of the exposed semiconductor fin 425. For example, the first source/drain region 450 may be provided as a LDD (Lightly Doped Drain) region. The semiconductor fin 425, the gate structure 440, and the first source/drain regions 450 may constitute or define a FinFET.

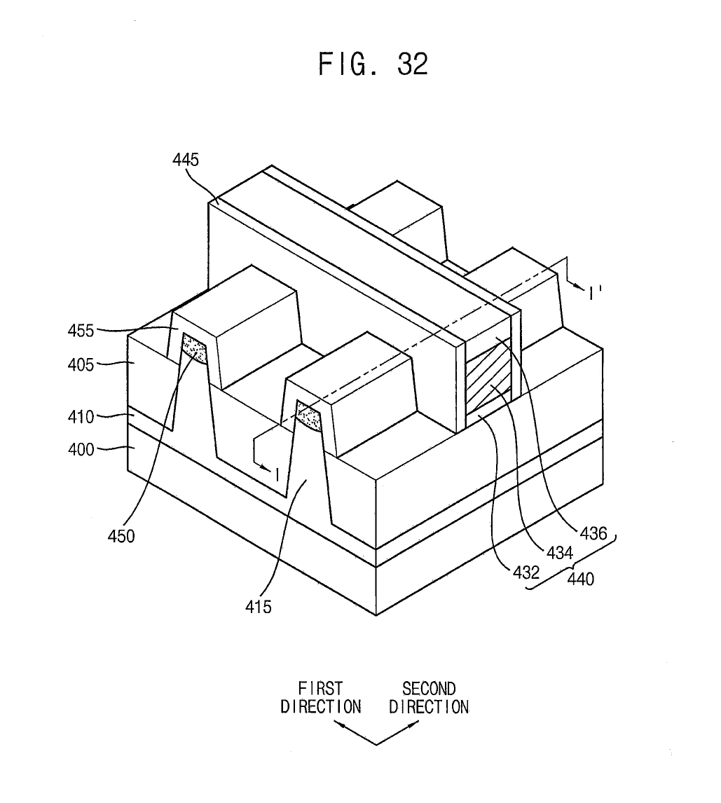

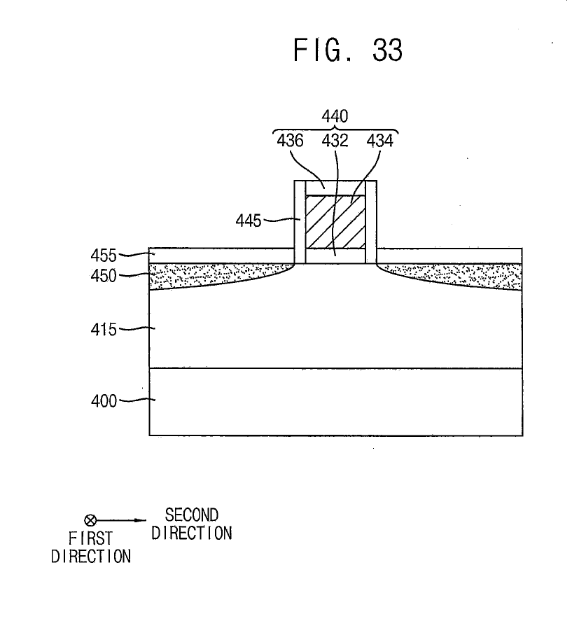

Referring to FIGS. 32 and 33, second source/drain regions 455 may further be formed on the semiconductor fin 425 and the first source/drain regions 450. For example, an elevated source/drain (ESD) film may be formed through a selective epitaxial growth (SEG) process using the semiconductor fin 425 and/or the first source/drain region 450 as a seed layer and using a silicon source gas (e.g., di-chlorosilane) as a reaction gas. The second source/drain region 455 may be completed by implanting impurities in the elevated source/drain film through an ion implantation process.

In some embodiments, in the SEG process, a germanium source gas and/or a hydrocarbon gas along with a silicon source gas may be injected. In this case, it is possible to facilitate the driving of the FinFET by applying a stress through the second source/drain regions 455.

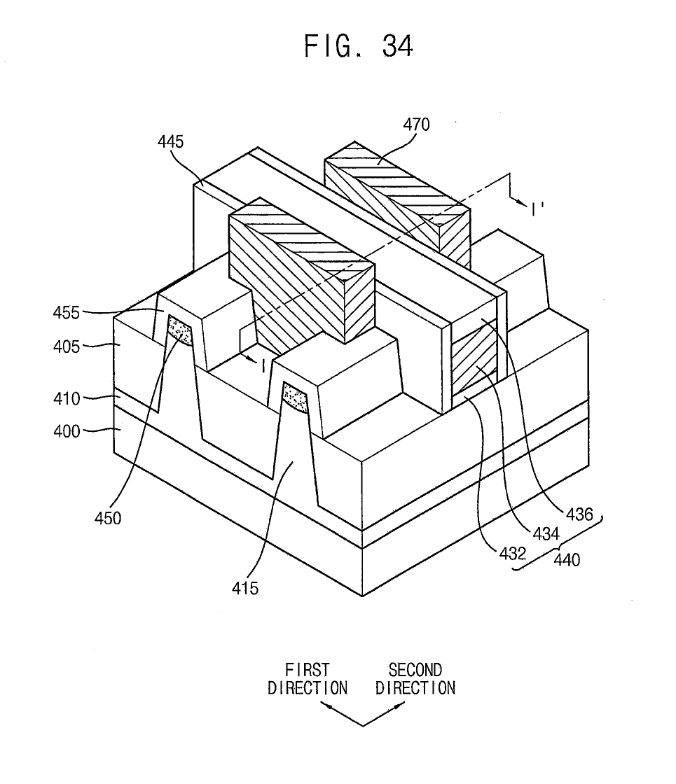

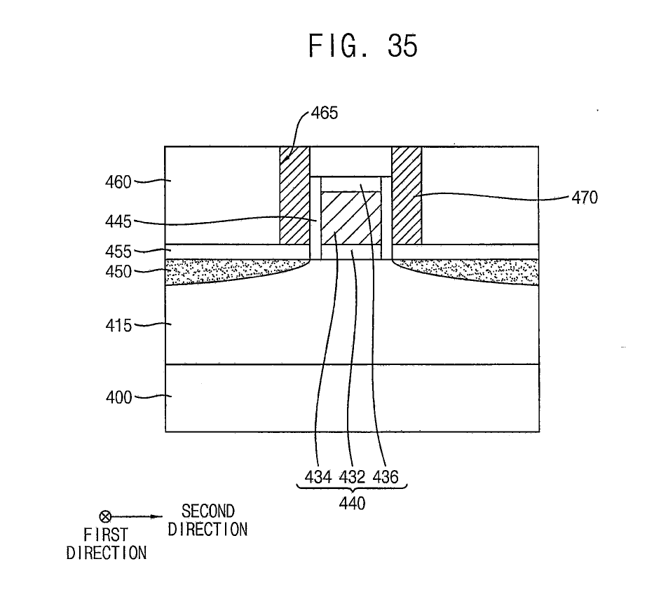

Referring to FIGS. 34 and 35, a source/drain contact 470 may be formed to be electrically connected to the second source/drain region 455. For example, a first lower insulating film 460 may be formed on the device isolation film 405 to extend onto or cover the second source/drain region 455, the gate spacer 445, and the gate structure 440. In FIG. 34, for convenience of illustration, the first lower insulating film 460 is omitted. The first lower insulating film 460 may be formed of a silicon oxide-based material through a CVD process. A contact hole 465 may be formed by partially etching the first lower insulating film 460 to at least partially expose the second source/drain region 455. The contact hole 465 may be self-aligned by the gate spacer 445. A preliminary contact film filling the contact hole 465 through the SEG process using the exposed second source/drain region 455 as a seed layer may be formed. The contact 470 may be formed by implanting impurities into the preliminary film through an ion implantation process. The contact 470 may fill the contact hole 465 and may connect the second source/drain region 455.

In some embodiments, the preliminary contact film may be formed of a metal, a metal nitride, a metal silicide, poly-silicon, amorphous silicon, or a combination thereof through an ALD process, a PVD process, or a CVD process.

In some embodiments, one contact hole 465 may expose a plurality of second source/drain regions 455. For example, at least two of the second source/drain regions 455 that are adjacent to each other in the first direction may be exposed by the one contact hole 465. In this case, as illustrated in FIG. 34, one contact 470 may be connected to two of the second source/drain regions 455. Accordingly, it is possible to increase an alignment tolerance for forming the contact 470. Furthermore, the second source/drain region 455 that is extended from the semiconductor fin 425 may function as a pad for contacting the contact 470. Therefore, the alignment tolerance may further increase by an extended width of the second source/drain region 455.

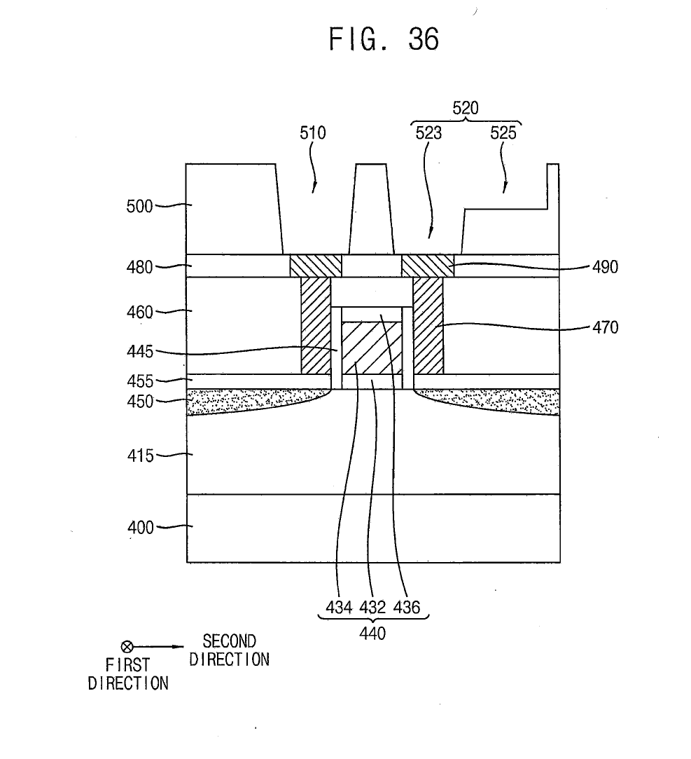

Referring to FIG. 36, the process being substantially similar to that described with reference to FIG. 2 may be performed. Therefore, a second lower insulating film 480 and a lower wiring 490 may be formed on the first lower insulating film 460 and the contact 470.

A back end-of-line (BEOL) process including the processes being substantially the same as or similar to those described with reference to FIGS. 3, and/or 16 through 18 may be performed. For example, an interlayer insulating film 500 may be formed on the second lower insulating film 480 and the lower wiring 490. A first opening 510 and a second opening 520 that expose each top surface of the lower wirings 490 may be formed by partially removing the interlayer insulating film 500.

In some embodiments, the first opening 510 may have a via-hole shape that is formed through a single damascene process. The second opening 520, as described with reference to FIGS. 17 and 18, may be formed through a double damascene process. For example, the second opening 520 may include a via-hole 523 that exposes the top surface of the lower wiring 490, and a trench 525 that connects the via-hole 523 at a top portion of the interlayer insulating film 500. The trench 525 may extend in the first direction.

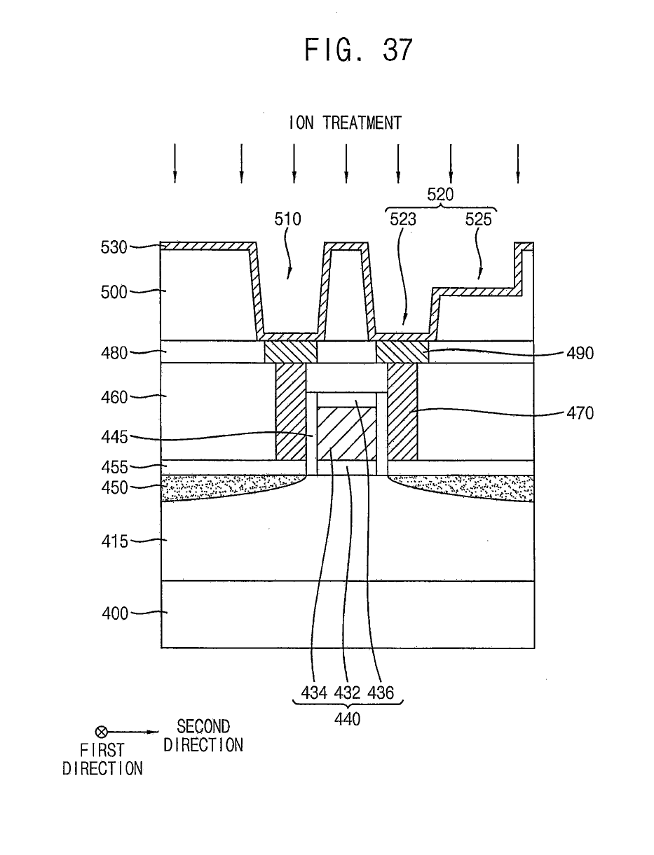

Referring to FIG. 37, the processes being substantially the same as or similar to those described with reference to FIGS. 4 through 6B, and/or 19 and 20 may be performed. For example, a liner film 530 having a uniform thickness may be formed along a top surface of the interlayer insulating film 500 and respective inner surfaces (i.e., side surfaces and bottom surfaces) of the first opening 510 and the second opening 520. The liner film 530 may be formed through a CVD-Ru process. The liner film 530 may have improved reflow characteristics through an annealing treatment and an ion bombardment treatment.

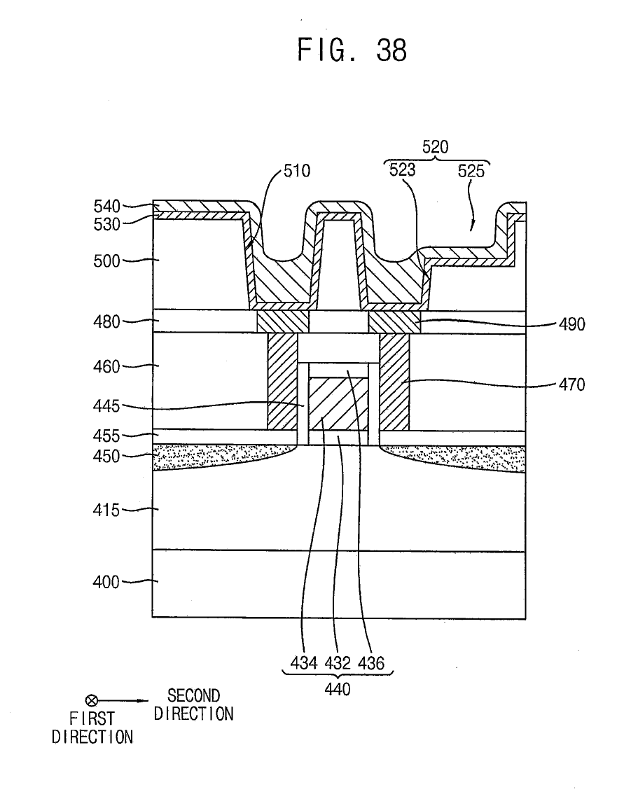

Referring to FIG. 38, the process being substantially the same as or similar to that described with reference to FIG. 7 and/or 21 may be performed. For example, a first metal film 540 that fills respective lower portions of the first opening 510 and the second opening 520 may be formed on the liner film 530 through a copper reflow process.

The first metal film 540 may partially fill the first opening 510 and the second opening 520, and may completely fill the via-hole 523 of the second opening 520. In some embodiments, the first metal film 540 may completely fill the first opening 510.

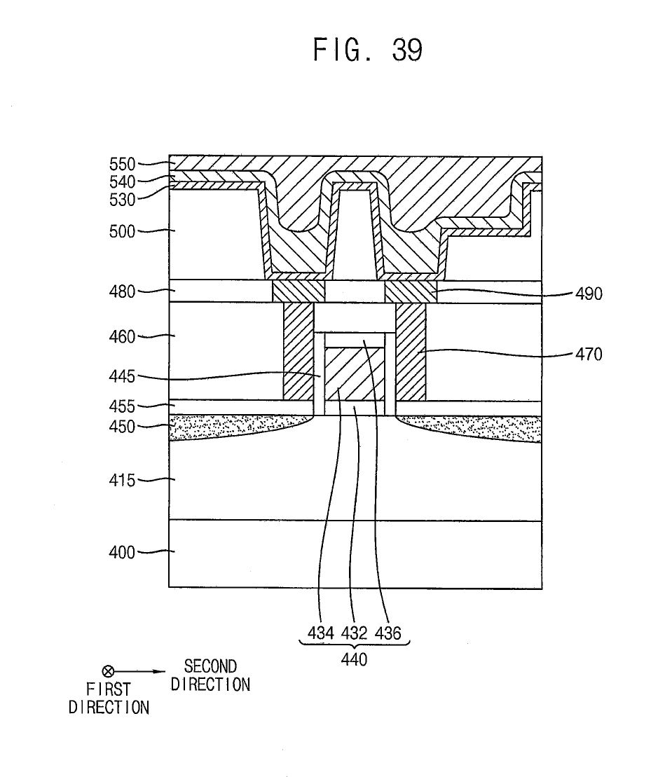

Referring to FIG. 39, through the process being substantially the same as or similar to that described with reference to FIG. 8 and/or 22, a second metal film 550 may be formed on the first metal film 540. For example, the second metal film 550 may be formed through a copper plating process and may fill the remaining portions of the first opening 510 and the second opening 520.

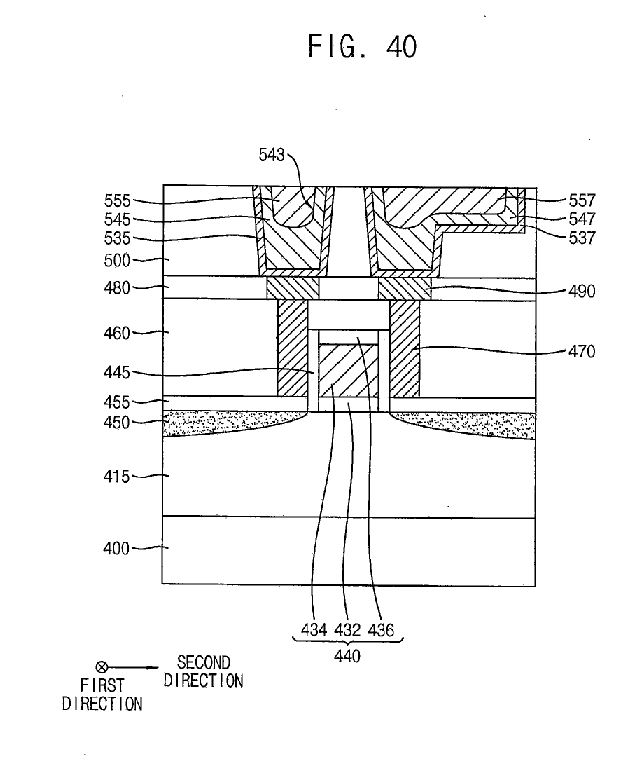

Referring to FIG. 40, respective upper portions of the second metal film 550, the first metal film 540, and the liner film 530 may be planarized through a CMP process and/or an etch-back process until the top surface of the interlayer insulating film 500 is exposed. Accordingly, a first wiring structure that includes a liner film pattern 535, a first metal film pattern 545, and a second metal film pattern 555 may be formed in the first opening 510. And, a second wiring structure that includes a liner film pattern 537, a first metal film pattern 547, and a second metal film pattern 557 in the opening 520.

A recess 543 may be defined by an inner surface of the first metal film pattern 545 that is formed in the first opening 510. The recess 543 may be filled with the second metal film pattern 555 of the first wiring structure. As described with reference to FIG. 7, the shortest distance between a bottom surface of the recess 543 and the bottom surface of the first opening 510 may be greater than the shortest distance between a side surface of the recess 543 and the side surface of the first opening 510.

The first metal film pattern 547 of the second wiring structure may completely fill the via-hole 523 and the second metal film pattern 557 of the second wiring structure may fill the remaining portion of the trench 525.

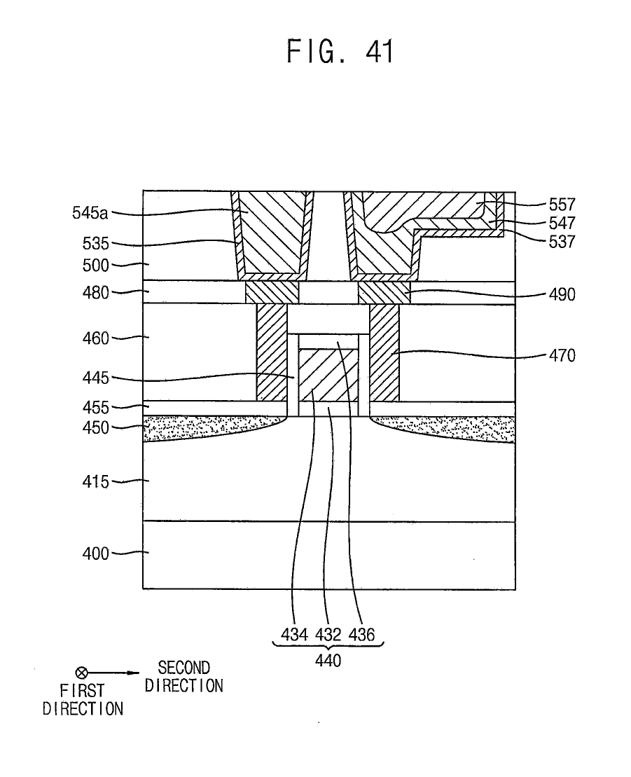

Referring to FIG. 41, in some embodiments, the first opening 510 may be completely filled with a first metal film pattern 545a. Therefore, the second metal film pattern 555 may be omitted in the first wiring structure.

According to example embodiments of the inventive concepts, a liner film (e.g., ruthenium Ru) having an overall uniform profile in an opening may be formed through a chemical vapour deposition (CVD) process. By treating a surface of the liner film by an ion bombardment, it may be possible to improve reflow characteristics of the surface of the liner film. As a result, since a metal seed such as copper (Cu) is sufficiently filled in the opening, it may be possible to form a wiring structure with high reliability in which defects such as a void and/or a seam are prevented or removed through a subsequent plating process.

According to the above-described example embodiments of the inventive concepts, the wiring structures and the methods of forming the same may be applicable to various semiconductor devices where a fine pattern having a width of less than approximately 20 nm or less than approximately 10 nm is required. For example, the wiring structures and the methods of forming the same may be applied to a logic device including a FinFET structure having a gate of a fine width, a volatile memory device such as a SRAM device or a DRAM device, and a non-volatile memory device such as a PRAM device, a MRAM device, or a RRAM device.

While the inventive concepts have been particularly shown and described with reference to example embodiments thereof, it will be understood that various changes in form and details may be made therein without departing from the spirit and scope of the following claims.

1. A method of forming a wiring structure in a semiconductor device, the method comprising:
forming a lower structure on a substrate;
forming an interlayer insulating film including an opening on the lower structure;
forming a liner film on an inner surface of the opening;
treating a surface of the liner film by an ion bombardment; and
forming a first conductive film on the liner film,
wherein the forming the first conductive film is performed such that the first conductive film is at least partially filled in the opening through a reflow process.

2. The method of claim 1, wherein the liner film comprises ruthenium and is formed through a chemical vapor deposition (CVD) process.

3. The method of claim 1, wherein the ion bombardment treatment is performed using an ion source including argon (Ar), helium (He), neon (Ne), krypton (Kr), xenon (Xe), radon (Rn), or combinations thereof through a plasma process.

4. The method of claim 1, wherein the first conductive film comprises copper (Cu) and is formed through the reflow process.

5. The method of claim 1, further comprising forming a second conductive film through a plating process using the first conductive film as a seed layer.

6. The method of claim 5, wherein the first conductive film comprises copper (Cu) and is formed through the reflow process, and wherein the second conductive film comprises copper (Cu) and is formed through the plating process.

7. The method of claim 5, wherein the first conductive film is formed to partially fill a lower portion of the opening so as to define a recessed region in an upper portion of the opening, and
wherein the second conductive film is formed to fill the recessed region.

8. The method of claim 7, wherein a shortest distance between a bottom surface of the recessed region and a bottom surface of the opening is greater than a shortest distance between a side surface of the recessed region and a side surface of the opening.

9. The method of claim 1, further comprising, prior to treating the surface of the liner film by the ion bombardment, treating the surface of the liner film by annealing in an inert gas atmosphere.

10-14. (canceled)

15. The method of claim 1, wherein the lower structure is formed to include a lower insulating film and a lower wiring, and the lower wiring is formed to be at least partially exposed by the opening.

16. The method of claim 15, wherein the opening is formed to include a via-hole that exposes the lower wiring and a trench that is connected to the via-hole in an upper portion of the interlayer insulating film.

17. The method of claim 16, wherein the first conductive film is formed to completely fill the via-hole and to extend on a side surface and a bottom surface of the trench.

18. The method of claim 17, further comprising:
forming a second conductive film filling the remaining portion of the trench, and wherein the second conductive film is formed to be grown from the first conductive film.

19. The method of claim 18, further comprising:
forming an upper insulating film on the interlayer insulating film, the upper insulating film is formed to have a hole that is offset with respect to the via-hole and exposes a portion of the second conductive film formed in the trench;
forming an upper liner film on an inner surface of the hole;
treating a surface of the upper liner film by a subsequent ion bombardment; and
forming an upper conductive film on the upper liner film, the upper conductive film at least partially filled in the hole through a reflow process.

20. A method of forming a wiring structure in a semiconductor device, the method comprising:
forming a lower structure on a substrate;
forming an interlayer insulating film including an opening on the lower structure;
conformally forming a liner film along an inner surface of the opening through a chemical vapor deposition (CVD) process;
treating a surface of the liner film by an ion bombardment;
forming a first metal film on the liner film through a reflow process, the first metal film is formed to include a first thickness measured from a bottom surface of the opening and a second thickness measured from a side surface of the opening less than the first thickness; and
forming a second metal film through a plating process using the first metal film as a seed.

21. The method of claim 20, further comprising, prior to treating the surface of the liner film by the ion bombardment, treating the surface of the liner film by an annealing in a hydrogen atmosphere.

22-32. (canceled)

33. A method of forming a wiring structure in a semiconductor device, the method comprising:
forming a conductive liner film on an underlying conductive wiring layer that is exposed by an opening in an interlayer insulating layer, wherein the conductive liner film extends on sidewalls of the opening;
performing an ion bombardment on a surface of the conductive liner film in the opening, wherein the ion bombardment increases a wettability characteristic of the surface of the conductive liner film; and
forming a first conductive film on the surface of the conductive liner film in the opening after performing the ion bombardment.

34-39. (canceled)

40. The method of claim 34, further comprising:
performing an anneal of the conductive liner film prior to performing the ion bombardment, wherein the anneal removes carbon-based impurities from the surface of the conductive liner film to increase an adhesion characteristic thereof.

41. The method of claim 40, wherein the anneal and the ion bombardment are sequentially performed ex-situ, wherein the anneal is performed at a temperature of 150° C. to 250° C., and wherein the ion bombardment is performed at a temperature of 300° C. to 400° C.

42. The method of claim 34, wherein the ion bombardment and the reflow process are sequentially performed in a same chamber in-situ.
